(19) United States
(12) Patent Application Publication
(10) Pub. No.: US 2025/0113625 A1
(43) Pub. Date: Apr. 3, 2025

(54) RADIATION DETECTOR

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Masahiro WATABE, Tokyo (JP)

(73) Assignee: Japan Display Inc., Tokyo (JP)

(21) Appl. No.: 18/897,125

(22) Filed: Sep. 26, 2024

(30) Foreign Application Priority Data
Sep. 28, 2023 (JP) 2023-168641

(51) Int. Cl. H01L 31/119; H01L 25/04; H01L 31/02; H01L 31/0224

(52) U.S. Cl. CPC H10F 30/298; H01L 25/042; H10F 77/206; H10F 77/933; H10F 77/953

(57) ABSTRACT

A radiation detector according to an embodiment of the present invention includes: a transistor in which an oxide semiconductor layer is used in a channel of the transistor; a photoelectric converting layer connected to the transistor; a wavelength converting layer facing the photoelectric converting layer and capable of emitting visible light based on radioactive rays absorbed by the wavelength converting layer; and an oxide layer in contact with the oxide semiconductor layer between the transistor and the photoelectric converting layer, wherein a thickness of the oxide layer is 50 nm or less.

### CROSS REFERENCE TO RELATED APPLICATIONS

This application claims the benefit of priority to Japanese Patent Application No. 2023-168641, filed on Sep. 28, 2023, the entire contents of which are incorporated herein by reference.

### FIELD

An embodiment of the present invention relates to a radiation detector. In particular, an embodiment of the present invention relates to a radiation detector including a semiconductor device in which an oxide semiconductor is used as a channel.

### BACKGROUND

In recent years, instead of amorphous silicon, low-temperature polysilicon, and single crystal silicon, development of a semiconductor device in which an oxide semiconductor is used as a channel has been advanced (for example, Japanese Laid-Open Patent Publication No. 2021-141338, Japanese Laid-Open Patent Publication No. 2014-099601, Japanese Laid-Open Patent Publication No. 2021-153196, Japanese Laid-Open Patent Publication No. 2018-006730, Japanese Laid-Open Patent Publication No. 2016-184771, and Japanese Laid-Open Patent Publication No. 2021-108405). The semiconductor device in which the oxide semiconductor is used as the channel can be formed by a simple structure and a low-temperature process similar to a semiconductor device in which amorphous silicon is used as a channel. It is known that the semiconductor device in which the oxide semiconductor is used as the channel has higher mobility than the semiconductor device in which the amorphous silicon is used as the channel.

In order for the semiconductor device in which the oxide semiconductor is used as the channel to operate stably, it is important to reduce oxygen vacancies formed in an oxide semiconductor layer by supplying oxygen to the oxide semiconductor layer in a manufacturing process of the semiconductor device. As a method of supplying oxygen to the oxide semiconductor layer, for example, a technique of forming an insulating layer covering the oxide semiconductor layer under a condition that the insulating layer contains more oxygen is disclosed.

### SUMMARY

A radiation detector according to an embodiment of the present invention includes: a transistor in which an oxide semiconductor layer is used in a channel of the transistor; a photoelectric converting layer connected to the transistor; a wavelength converting layer facing the photoelectric converting layer and capable of emitting visible light based on radioactive rays absorbed by the wavelength converting layer; and an oxide layer in contact with the oxide semiconductor layer between the transistor and the photoelectric converting layer, wherein a thickness of the oxide layer is 50 nm or less.

### BRIEF DESCRIPTION OF DRAWINGS

FIG. 1 is a cross-sectional view showing an outline of a radiation detector according to an embodiment of the present invention.

FIG. 2 is a circuit diagram showing an outline of a radiation detector according to an embodiment of the present invention.

FIG. 3 is a diagram showing results of a reliability test on visible light of a transistor used in a radiation detector according to an embodiment of the present invention.

FIG. 4 is a diagram showing results of a reliability test on radiation of a transistor used in a radiation detector according to an embodiment of the present invention.

FIG. 5 is a diagram showing results of a reliability test on radiation of a transistor used in a radiation detector according to an embodiment of the present invention.

FIG. 6 is a diagram showing results of a reliability test on visible light of a transistor used in a radiation detector according to an embodiment of the present invention.

FIG. 7 is a diagram showing results of a reliability test on visible light of a transistor used in a radiation detector according to an embodiment of the present invention.

### DESCRIPTION OF EMBODIMENTS

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, thicknesses, shapes, and the like of respective portions as compared with actual embodiments. However, the shown shapes are merely examples, and do not limit the interpretation of the present invention. In the present specification and the drawings, the same reference signs are given to the same components as those described above with respect to the drawings already described and detailed description thereof may be omitted as appropriate.

In each embodiment of the present invention, a direction from a substrate toward an oxide semiconductor layer is referred to as “up” or “above”. Conversely, a direction from the oxide semiconductor layer toward the substrate is referred to as “down” or “lower”. Thus, for convenience of explanation, although the term “upper” or “lower” will be used for explanation, for example, the vertical relationship between the substrate and the oxide semiconductor layer may be arranged in a direction different from that shown in the diagrams. In the following description, for example, the expression “oxide semiconductor layer on the substrate” merely describes the vertical relationship between the substrate and the oxide semiconductor layer as described above, and other members may be disposed between the substrate and the oxide semiconductor layer. An upper portion or a lower portion means a stacking order in a structure in which a plurality of layers are stacked, and in the case where a first member is expressed as the first member above the transistor, the transistor and the first member may have a positional relationship in which the transistor and the first member do not overlap in a plan view. On the other hand, the expression “first member vertically above the transistor” means a positional relationship in which the transistor and the first member overlap in a plan view.

As used herein, the phrase “a comprises A, B, or C,” “a comprises any of A, B, or C,” “a comprises one selected from a group consisting of A, B, and C,” and the like does not exclude cases where a comprises a plurality of combinations of A to C unless otherwise indicated. Furthermore, these expressions do not exclude the case where a includes other elements.

In addition, the following embodiments can be combined with each other as long as there is no technical inconsistency.

An insulating layer formed under a condition of containing more oxygen contains many defects. Due to this effect, a characteristic variation of the semiconductor device in a reliability test occurs. The characteristic variation in the reliability test is considered to be caused by the trapping of holes in the defects in the insulating layer. In the case where a semiconductor device in which a hole trap is formed is used in a detector for radiation, a characteristic variation of the semiconductor device occurs due to trapping of a hole generated by irradiation of the radiation. It is required to suppress such characteristic variation.

An object of an embodiment of the present invention is to realize a highly reliable radiation detector.

### 1. First Embodiment

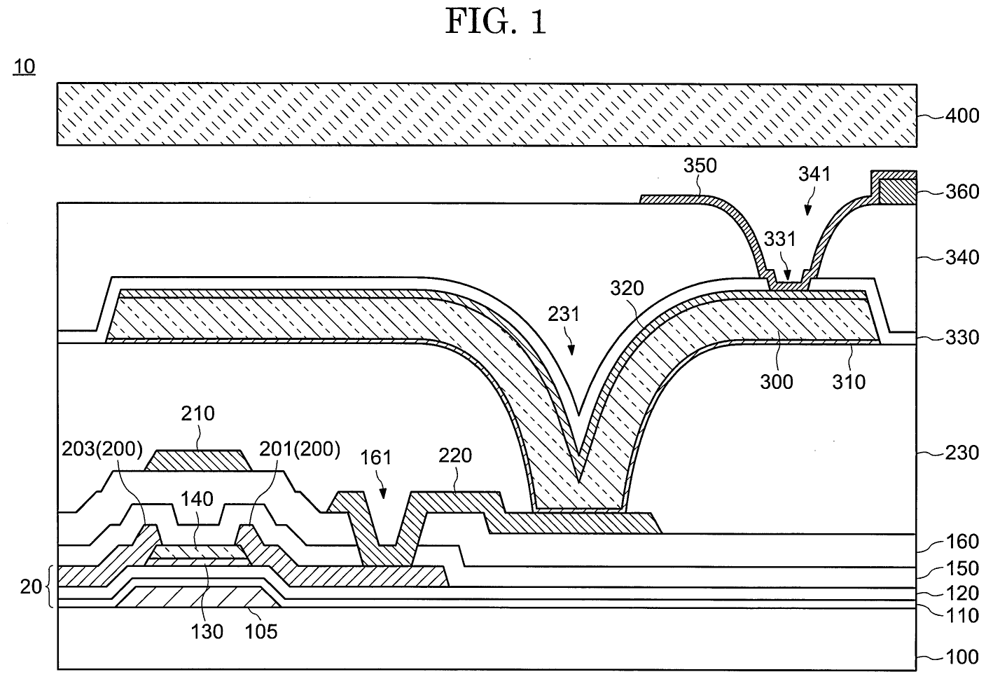

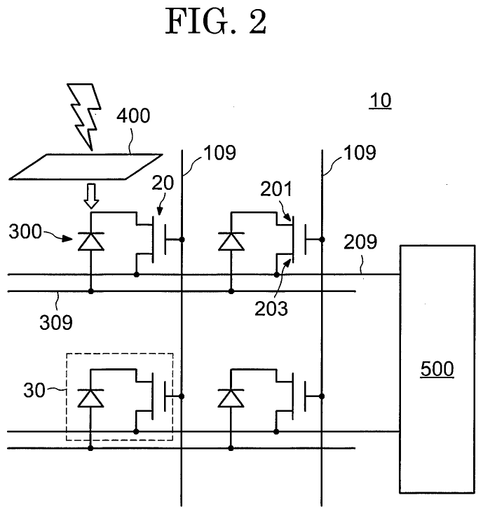

Referring to FIG. 1 and FIG. 2, a radiation detector 10 according to an embodiment of the present invention will be described.

### [1-1. Configuration of the Radiation Detecting Apparatus 10]

With reference to FIG. 1 and FIG. 2, a configuration of the radiation detecting apparatus 10 according to an embodiment of the present invention will be described. FIG. 1 is a cross-sectional view showing an outline of a radiation detector according to an embodiment of the present invention. FIG. 2 is a circuit diagram showing an outline of a radiation detector according to an embodiment of the present invention.

As shown in FIG. 1, the radiation detector 10 is provided on a substrate 100. The radiation detector 10 includes a transistor 20, a photoelectric converting layer 300, a wavelength converting layer 400, and an oxide layer 150. The radiation detector 10 includes, in addition to the members described above, an insulating layer 160, a light shielding layer 210, a connection wiring 220, an insulating layer 230, a lower electrode 310, an upper electrode 320, insulating layers 330 and 340, and wirings 350 and 360.

The transistor 20 includes a gate electrode 105, gate insulating layers 110 and 120, a metal oxide layer 130, an oxide semiconductor layer 140, a source electrode 201, and a drain electrode 203. The transistor 20 is a transistor in which the oxide semiconductor layer 140 is used as a channel. Depending on the polarity of the transistor, a circuit configuration, and the potential of each node, the source electrode and the drain electrode of the transistor may be interchanged with each other. In the case where the source electrode 201 and the drain electrode 203 are not particularly distinguished from each other, they may be collectively referred to as a source-drain electrode 200. In the present embodiment, a bottom-gate transistor in which the gate electrode 105 is provided below the oxide semiconductor layer 140 as the radiation detector 10 will be described.

In the present embodiment, although a bottom-gate transistor in which the oxide semiconductor layer 140 is closer to the photoelectric converting layer 300 than the gate electrode 105 is exemplified as the radiation detector 10, the radiation detector 10 is not limited to the bottom-gate transistor. For example, the radiation detector 10 may be a dual-gate transistor in which a gate electrode is provided both above and below the oxide semiconductor layer 140.

The gate electrode 105 is provided on the substrate 100. The gate electrode 105 faces the oxide semiconductor layer 140. The gate insulating layers 110 and 120 are provided between the gate electrode 105 and the oxide semiconductor layer 140. The gate insulating layers 110 and 120 have a stacked structure. The metal oxide layer 130 is provided on the gate insulating layer 120. The oxide semiconductor layer 140 is provided on the metal oxide layer 130. A source electrode 201 and a drain electrode 203 are provided on the oxide semiconductor layer 140. The source electrode 201 and the drain electrode 203 are in contact with the oxide semiconductor layer 140 from above the oxide semiconductor layer 140.

The oxide layer 150 and the insulating layer 160 are provided on the oxide semiconductor layer 140, the source electrode 201, and the drain electrode 203. The oxide layer 150 and the insulating layer 160 have a stacked structure. The insulating layer 160 is provided on the oxide layer 150. The oxide layer 150 and the insulating layer 160 cover the source electrode 201 and the drain electrode 203. The oxide layer 150 is in contact with the oxide semiconductor layer 140. It can be said that the oxide layer 150 is provided between the transistor 20 and the photoelectric converting layer 300.

The oxide semiconductor layer 140 has translucency and has a polycrystalline structure including a plurality of crystal grains. As will be described later, the oxide semiconductor layer 140 having the polycrystalline structure can be formed by using a Poly-OS (Poly-crystalline Oxide Semiconductor) technique. Hereinafter, although the structure of the oxide semiconductor layer 140 will be described, an oxide semiconductor having a polycrystalline structure may be referred to as a Poly-OS.

A grain size of the crystal grains contained in the Poly-OS is, for example, 0.1 μm or more, 0.3 μm or more, or 0.5 μm or more. The grain size of the crystal grains can be obtained by, for example, a cross-sectional SEM observation, a cross-sectional TEM observation, or an electron back scattered diffraction (EBSD) method.

As described above, since the grain size of the crystal grains included in the Poly-OS is 0.1 μm or more, in the oxide semiconductor layer 140 having a film thickness of 10 nm or more and 30 nm or less, there are regions including only one crystal grain along the film thickness.

A thickness of the gate insulating layer 110 is, for example, 50 nm or more and 500 nm or less, 50 nm or more and 400 nm or less, 50 nm or more and 300 nm or less, 50 nm or more and 150 nm or less, or 50 nm or more and 100 nm. A thickness of the gate insulating layer 120 is, for example, 10 nm or more and 200 nm or less or 10 nm or more and 100 nm or less. A total thickness of the gate insulating layers 110 and 120 is, for example, 100 nm or more and 700 nm or less, 100 nm or more and 500 nm or less, 100 nm or more and 400 nm or less, 100 nm or more and 250 nm or less, 100 nm or more and 200 nm or less, or 100 nm or more and 150 nm or less.

A thickness of the metal oxide layer 130 is, for example, 1 nm or more and 20 nm or less or 1 nm or more and 10 nm or less. In the present embodiment, aluminum oxide is used as the metal oxide layer 130. Aluminum oxide has a high barrier property against gases such as oxygen or hydrogen. The barrier property means a function of suppressing the permeation of a gas such as oxygen or hydrogen through the aluminum oxide. That is, even if a gas such as oxygen or hydrogen is released from a layer provided below an aluminum oxide film, the gas does not move to a layer provided above the aluminum oxide film. Alternatively, even if the gas such as oxygen or hydrogen is released from the layer provided above the aluminum oxide film, the gas does not move to the layer provided below the aluminum oxide film.

A thickness of the oxide semiconductor layer 140 is 10 nm or more and 50 nm or less, 10 nm or more and 40 nm or less, or 10 nm or more and 30 nm or less. A thickness of the oxide layers 150 is 50 nm or more and 300 nm or less, 60 nm or more and 200 nm or less, or 70 nm or more and 150 nm or less.

The thickness of the oxide layer 150 is, for example, 100 nm or less, 50 nm or less, 30 nm or less, 20 nm or less, or 10 nm or less. Since the thickness of the oxide layer 150 falls within the above range, reliability of the transistor 20 with respect to visible light and radiation is improved, as will be described later.

A thickness of the insulating layer 160 is, for example, 50 nm or more and 500 nm or less, 50 nm or more and 400 nm or less, 50 nm or more and 300 nm or less, or 50 nm or more and 200 nm or less.

The light shielding layer 210 is provided on the insulating layer 160. The light shielding layer 210 is provided in a region overlapping the oxide semiconductor layer 140 in a plan view. In a top view, the light shielding layer 210 is provided so as to cover at least the oxide semiconductor layer 140 exposed from the source-drain electrode 200. In the case where the light shielding layer 210 is formed of a conductive material, the same voltage as that of the gate electrode 105 may be supplied to the light shielding layer 210. In this case, the transistor 20 functions as a dual-gate transistor.

Openings 161 are provided on the oxide layer 150 and the insulating layer 160. The openings 161 reach the source electrode 201. The connection wiring 220 is provided on the insulating layer 160 and inside the opening 161. The connection wiring 220 is in contact with the source electrode 201 at a bottom portion of the opening 161.

The insulating layer 230 is provided on the insulating layer 160, the light shielding layer 210, and the connection wiring 220. The insulating layer 230 covers a pattern end portion of the light shielding layer 210 and a pattern end portion of the connection wiring 220. The insulating layer 230 alleviates a step formed by the light shielding layer 210 and the connection wiring 220. The insulating layer 230 may be referred to as a planarization layer. An organic insulating layer is used as the insulating layer 230. An opening 231 is provided on the insulating layer 230. The opening 231 reaches the connection wiring 220.

The lower electrode 310 is provided on the insulating layer 230 and inside the opening 231. The lower electrode 310 is in contact with the connection wiring 220 at a bottom portion of the opening 231. The photoelectric converting layer 300 and the upper electrode 320 are provided on the lower electrode 310. That is, the photoelectric converting layer 300 is connected to the transistor 20 via the lower electrode 310 and the connection wiring 220. The photoelectric converting layer 300 includes an N-type semiconductor layer, a P-type semiconductor layer, and an intrinsic semiconductor layer. The intrinsic semiconductor layer is provided between the N-type semiconductor layer and the P-type semiconductor layer. One of the N-type semiconductor layer and the P-type semiconductor layer is in contact with the lower electrode 310, and the other is in contact with the upper electrode 320.

The photoelectric converting layer 300 has a function of converting light energy into electrical energy. When the light energy is absorbed by the intrinsic semiconductor layer of the photoelectric converting layer 300, the semiconductor is photoexcited to generate a pair of electrons and holes. The generated electrons and holes flow through the N-type semiconductor layer and the P-type semiconductor layer to the lower electrode 310 and the upper electrode 320. The intensity of the light irradiated to the photoelectric converting layer 300 can be detected by detecting a current generated by the electrons and the holes generated by the photoexcitation.

The insulating layer 330 is provided on the upper electrode 320. An opening 331 is provided on the insulating layer 330. The opening 331 reaches the upper electrode 320. The insulating layer 340 is provided on the insulating layer 330. An opening 341 is provided on the insulating layer 340. In a plan view, the opening 341 is larger than the opening 331. The opening 341 reaches portions of the upper electrode 320 and the insulating layer 330. An inorganic insulating layer is used as the insulating layer 330. An organic insulating layer is used as the insulating layer 340. The insulating layer 330 has a shape reflecting steps formed by the lower electrode 310, the photoelectric converting layer 300, and the upper electrode 320. On the other hand, the insulating layer 340 alleviates the steps. That is, the insulating layer 340 is a planarization layer.

The wiring 360 is provided on the insulating layer 340 and in a region not overlapping the photoelectric converting layer 300 in a plan view. The wiring 350 is provided on the insulating layer 340, on the wiring 360, and inside the opening 341. The wiring 350 is in contact with the upper electrode 320 at a bottom portion of the opening 341.

As will be described in detail later, in order for visible light emitted from the wavelength converting layer 400 to efficiently reach the photoelectric converting layer 300, a transparent conductive layer is used as the upper electrode 320 and the wiring 350. On the other hand, the wiring 360 is an opaque metal layer. The electrical resistance of the metal layer used as the wiring 360 is lower than the electrical resistance of the transparent conductive layer used as the wiring 350. However, a transparent conductive layer may be used as the wiring 360.

The wavelength converting layer 400 is provided above the wiring 350 so as to face the photoelectric converting layer 300. The wavelength converting layer 400 may be bonded to the wiring 350 and the insulating layer 340 by an adhesive layer, or a positional relationship between the wiring 350 and the insulating layer 340 may be fixed by a different fixing member. The wavelength converting layer 400 has a function of converting radiation into visible light. For example, the wavelength converting layer 400 includes a phosphor that absorbs X-rays, α-rays, or γ-rays and emits visible light. The wavelength converting layer 400 may be referred to as a scintillator.

When radiation enters the wavelength converting layer 400 from above, the radiation is converted into visible light by the wavelength converting layer 400. When the converted visible light enters the photoelectric converting layer 300, light energy is converted into electric energy, and the converted electric energy is detected as a current. Since there is a correlation between the intensity of the radiation incident on the wavelength converting layer 400 and the detected current, the intensity of the radiation can be evaluated from a magnitude of the current.

As shown in FIG. 2, pixels 30 are arranged in a matrix in the radiation detector 10. The pixel 30 includes the transistor 20 and the photoelectric converting layer 300. The gate electrode of the transistor 20 is connected to a gate control line 109. The source electrode 201 of the transistor 20 is connected to a cathode of the photoelectric converting layer 300. An anode of the photoelectric converting layer 300 is connected to a wiring 309. The drain electrode 203 of the transistor 20 is connected to a wiring 209. The wiring 209 is connected to a charge amplifier circuit 500.

As described above, the radiation incident on the wavelength converting layer 400 is converted into visible light, and the visible light is converted into electric energy by the photoelectric converting layer 300. Here, by supplying a bias voltage to the wiring 309 connected to the pixel 30 for detecting radiation and controlling the gate control line 109 connected to the pixel 30 to an on state, the electric energy is detected as a current flowing through the transistor 20. The current flowing through the transistor 20 is supplied to the charge amplifier circuit 500 via the wiring 209. Then, the charge amplifier circuit 500 converts a charge signal into a voltage signal, and outputs the voltage signal to the outside. It is possible to evaluate the intensity of the radiation irradiated to the pixel 30 by the above operation.

As shown in FIG. 1, ideally, all of the radiation incident from above is absorbed by the wavelength converting layer 400, but in practice, part of the radiation is transmitted through the wavelength converting layer 400. Further, ideally, the radiation transmitted through the wavelength converting layer 400 is blocked by the light shielding layer 210, but in practice, the radiation passes around the light shielding layer 210 due to reflection by another member or the like, and reaches the oxide semiconductor layer 140. When radiation enters the oxide semiconductor layer 140, a pair of electrons and holes are generated in the oxide semiconductor layer 140. Since a hole trap is formed in the oxide layer 150 in contact with the oxide semiconductor layer 140, the generated hole is trapped in the oxide layer 150. This may cause a problem in that the electrical characteristics of the transistor 20 shift in a negative direction.

### [1-2. Material of Each Member of Radiation Detector 10]

As the substrate 100, a rigid substrate having translucency, such as a glass substrate, a quartz substrate, or a sapphire substrate, is used. In the case where the substrate 100 needs to have flexibility, a substrate containing a resin such as a polyimide substrate, an acrylic substrate, a siloxane substrate, or a fluorine resin substrate is used as the substrate 100. In the case where a substrate containing a resin is used as the substrate 100, impurities may be introduced into the resin in order to improve heat resistance of the substrate 100. A substrate that does not have translucency, such as a silicon substrate, a silicon carbide substrate, a semiconductor substrate such as a compound semiconductor substrate, or a conductive substrate such as a stainless steel substrate, may be used as the substrate 100.

General metal materials are used as the gate electrode 105, the source-drain electrode 200, the light shielding layer 210, the connection wiring 220, the lower electrode 310, and the wiring 360. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof are used as these members. As these electrodes and wirings, the materials described above may be used in a single layer or in a stacked layer. In the case where the light shielding layer 210 does not need to be electrically conductive, a black resin may be used as the light shielding layer 210.

A transparent conductive layer is used as the upper electrode 320 and the wiring 350. As the transparent conductive layers, a mixture of indium oxide and tin oxide (ITO) and a mixture of indium oxide and zinc oxide (IZO) may be used. A material other than the above may be used as the transparent conductive layer.

A general insulating material is used as the gate insulating layers 110 and 120, the oxide layer 150, and the insulating layers 160 and 330. For example, as the gate insulating layer 120 and the oxide layer 150, an inorganic insulating layer containing oxygen such as silicon oxide (SiOₓ), silicon oxynitride (SiOₓN_{y}), aluminum oxide (AlOₓ), or aluminum oxynitride (AlOₓN_{y}) is used. As the gate insulating layer 110 and the insulating layer 160, an inorganic insulating layer containing nitrogen such as silicon nitride (SiNₓ), silicon nitride oxide (SiNₓO_{y}), aluminum nitride (AlNₓ), or aluminum nitride oxide (AlNₓO_{y}) is used. However, the inorganic insulating layer containing oxygen as described above may also be used as the gate insulating layer 110 and the insulating layer 160. The inorganic insulating layer containing nitrogen as described above may also be used as the gate insulating layer 120 and the oxide layer 150.

As the oxide layer 150, an insulating layer having a function of releasing oxygen by a heat treatment is used. That is, an oxide insulating layer containing an excess of oxygen is used as the oxide layer 150. The temperature of the heat treatment in which the oxide layer 150 releases oxygen is, for example, 600° C. or less, 500° C. or less, 450° C. or less, or 400° C. or less. That is, the oxide layer 150 emits oxygen at a heat treatment temperature performed in a manufacturing process of the transistor 20 in the case where a glass substrate is used as the substrate 100, for example.

As will be described in detail later, the oxide layer 150 is a layer having a different film quality depending on the film thickness direction. Specifically, the oxide layer 150 in a vicinity of the oxide semiconductor layer 140 has a smaller amount of hole traps than the other oxide layers 150. For convenience of explanation, in the oxide layer 150, a region near the oxide semiconductor layer 140 may be referred to as a first region, and other regions may be referred to as a second region. In this case, it can be said that an amount of hole traps formed in the oxide layer 150 in the first region is smaller than an amount of hole traps formed in the oxide layer 150 in the second region. Similarly, it can be said that the first region of the oxide layer 150 is in contact with the oxide semiconductor layer 140. The first region is only a region near the oxide semiconductor layer 140. That is, the first region is thinner than the second region.

As the gate insulating layer 120, an insulating layer with few defects is used. For example, if the composition ratio of oxygen in the gate insulating layer 120 is compared with the composition ratio of oxygen in an insulating layer having the same composition as that of the gate insulating layer 120 (hereinafter referred to as “other insulating layer”), the composition ratio of oxygen in the gate insulating layer 120 is closer to a stoichiometric ratio with respect to the insulating layer than the composition ratio of oxygen in the other insulating layer. Specifically, in the case where silicon oxide (SiOₓ) is used for each of the gate insulating layer 120 and the oxide layer 150, the composition ratio of oxygen in the silicon oxide used as the gate insulating layer 120 is closer to a stoichiometric ratio of silicon oxide than the composition ratio of oxygen in the silicon oxide used as the oxide layer 150. For example, as the gate insulating layer 120, a layer in which no defects are observed when evaluated by electron-spin resonance (ESR) may be used.

SiOₓN_{y} and AlOₓN_{y} are silicon-containing and aluminum-containing compounds that contain a smaller proportion of nitrogen (N) than oxygen (O) (x>y). SiNₓO_{y} and AlNₓO_{y} are silicon-containing and aluminum-containing compounds that contain a smaller proportion of oxygen than nitrogen (x>y).

An organic insulating layer is used as the insulating layers 230 and 340. For example, as the organic insulating layer, polyimide resin, acrylic resin, epoxy resin, silicone resin, fluorine resin, and siloxane resin are used.

As the metal oxide layer 130, a metal oxide containing aluminum as a main component is used. For example, an inorganic insulating layer such as aluminum oxide (AlOₓ) or aluminum oxynitride (AlOₓN_{y}) is used as the metal oxide layer 130. The “metal oxide layer 130 containing aluminum as a main component” means that the ratio of aluminum contained in the metal oxide layer 130 is 1% or more of the entire metal oxide layer. The ratio of aluminum contained in the metal oxide layer 130 may be 5% or more and 70% or less, 10% or more and 60% or less, or 30% or more and 50% or less of the entire metal oxide layer. The ratio described above may be a mass ratio or a weight ratio.

As the oxide semiconductor layer 140, a metal oxide having characteristics of a semiconductor is used. The oxide semiconductor layer 140 has a polycrystalline structure. The polycrystalline oxide semiconductor layer 140 can be fabricated using the Poly-OS technique.

For example, an oxide semiconductor containing indium (In), gallium (Ga), zinc (Zn), and oxygen (O) may be used as the oxide semiconductor layer 140. For example, an oxide semiconductor having a composition ratio of In:Ga:Zn:O=1:1:1:4 may be used as the oxide semiconductor layer 140. However, the oxide semiconductors including In, Ga, Zn, and O used in the present embodiment are not limited to the components described above. As the oxide semiconductor, an oxide semiconductor having a composition different from that described above may be used. For example, an oxide semiconductor layer having a higher ratio of In than those described above may be used in order to improve mobility. On the other hand, an oxide semiconductor layer having a higher ratio of Ga than those described above may be used in order to enlarge a bandgap and reduce the effects of light irradiation.

For example, as the oxide semiconductor layer 140 in which the ratio of In is larger than those described above, an oxide semiconductor containing two or more metals containing indium (In) may be used. In this case, in the oxide semiconductor layer 140, the ratio of indium elements to the total amount of metal elements may be 50% or more in an atomic ratio. In addition to indium, gallium (Ga), zinc (Zn), aluminum (Al), hafnium (Hf), yttrium (Y), zirconia (Zr), and lanthanoids may be used as the oxide semiconductor layer 140. As the oxide semiconductor layer 140, an element other than the elements described above may be used.

As the oxide semiconductor layers 140, other elements may be added to an oxide semiconductor containing In, Ga, Zn, and O, and a metallic element such as Al or Sn may be added. In addition to the oxide semiconductor described above, an oxide semiconductor containing In and Zn (IZO), an oxide semiconductor containing In, Sn, and Zn (ITZO), an oxide semiconductor containing In, Sn, Ga, and Zn (ITGZO), and an oxide semiconductor containing In and Ga (IGO), or the like may be used as the oxide semiconductor layer 140.

In the case where the ratio of the indium element is large, the oxide semiconductor layer 140 is easily crystallized. As described above, in the oxide semiconductor layer 140, the oxide semiconductor layer 140 having the polycrystalline structure can be easily obtained by using a material in which the ratio of the indium element to the entire metal element is 50% or more. The oxide semiconductor layer 140 preferably contains gallium as a metal element other than indium. Gallium belongs to the same Group 13 element as indium. Therefore, crystallinity of the oxide semiconductor layer 140 is not inhibited by gallium, and the oxide semiconductor layer 140 has the polycrystalline structure.

The oxide semiconductor layer 140 can be formed using a sputtering method. A composition of the oxide semiconductor layer 140 formed by the sputtering method depends on a composition of a sputtering target. Even in the case where the oxide semiconductor layer 140 has the polycrystalline structure, the composition of the sputtering target and the composition of the oxide semiconductor layer 140 substantially coincide with each other. In this case, the composition of the metal element of the oxide semiconductor layer 140 can be specified based on the composition of the metal element of the sputtering target.

In the case where the oxide semiconductor layer 140 has the polycrystalline structure, the composition of the oxide semiconductor layer may be specified using an X-ray Diffraction (XRD) method. Specifically, the composition of the metallic element of the oxide semiconductor layer can be specified based on the crystal structure and a lattice constant of the oxide semiconductor layer obtained by the XRD method. In addition, the composition of the metallic element of the oxide semiconductor layer 140 can also be determined using fluorescent X-ray analysis, or Electron Probe Micro Analyzer (EPMA) analysis, or the like. However, the oxygen element contained in the oxide semiconductor layer 140 varies depending on the process conditions of sputtering and the like, and thus cannot be specified by these methods in some cases.

### [1-3. Film Forming Method of Oxide Layer 150]

As described above, the oxide layer 150 included in the radiation detector 10 according to the present embodiment is a region near the oxide semiconductor layer 140 and includes the first region having relatively few hole traps and the second region located above the first region and having relatively many hole traps. The difference between the oxide layers 150 in the first region and the second region is caused by a film forming method of the oxide layer 150.

A film forming step in the case of forming the silicon oxide layer as the oxide layer 150 includes the following steps (1) to (2). The oxide layer 150 in the first region is formed by the step (1), and the oxide layer 150 in the second region is formed by the step (2).
(1) Interface formation process
(2) Bulk formation process

(1) Processing conditions of an interface formation process are as follows.

$$\begin{matrix}{SiH}_{4} / {N}_{2} O flow rate = 3 / 1000 sccm \\ Chamber pressure = 200 Pa \\ Power RF = 20 W \\ F ratio ( RF / {SiH}_{4} ) = 6.7 \\ Film thickness = 10 nm\end{matrix}$$

(2) Processing conditions of a bulk formation process are as follows.

$$\begin{matrix}{SiH}_{4} / {N}_{2} O flow rate = 10 / 1000 sccm \\ Chamber pressure = 333 Pa \\ Power RF = 200 W \\ F ratio ( RF / {SiH}_{4} ) = 10. \\ Film thickness = arbitrary\end{matrix}$$

In the present embodiment, the electrode size of a CVD device used to deposit the oxide layer 150 is circular with a radius of 9 cm, and an area of the electrode of the CVD device is 254 cm². Therefore, power density of the RF power (20 W) in (1) the interface formation process is 0.079 W/cm². Power density of the RF power (200 W) in (2) the bulk formation process is 0.79 W/cm².

As described above, regarding the film formation power (RF power) in the sputtering method, the RF power (20 W) in the film formation of the oxide layer 150 in the first region is lower than the RF power (200 W) in the film formation of the oxide layer 150 in the second region. Similarly, the ratio of SiH₄ gas to N₂O gas (3/1000) in the formation of the oxide layer 150 in the first region is smaller than the ratio of SiH₄ gas to N₂O gas (10/1000) in the formation of the oxide layer 150 in the second region. Similarly, the ratio of RF power to SiH₄ gas (6.7) in the film formation of the oxide layer 150 in the first region is smaller than the ratio of RF power to SiH₄ gas (10) in the film formation of the oxide layer 150 in the second region.

As described above, it is possible to form an oxide layer having a small amount of hole traps as the oxide layer 150 in the vicinity of the oxide semiconductor layer 140 by forming the oxide layer 150 in the first region in contact with the oxide semiconductor layer 140 with low power. As will be described later, the amount of hole traps contained in the oxide layer 150 can be reduced by the thickness of the oxide layer 150 being 100 nm or less or 50 nm or less. As a result, it is possible to suppress characteristic variation of the transistor 20 caused by the holes generated in the oxide semiconductor layer 140 being trapped in the oxide layer 150 by the incidence of the radiation.

### [1-4. Reliability Test Results of Transistor 20]

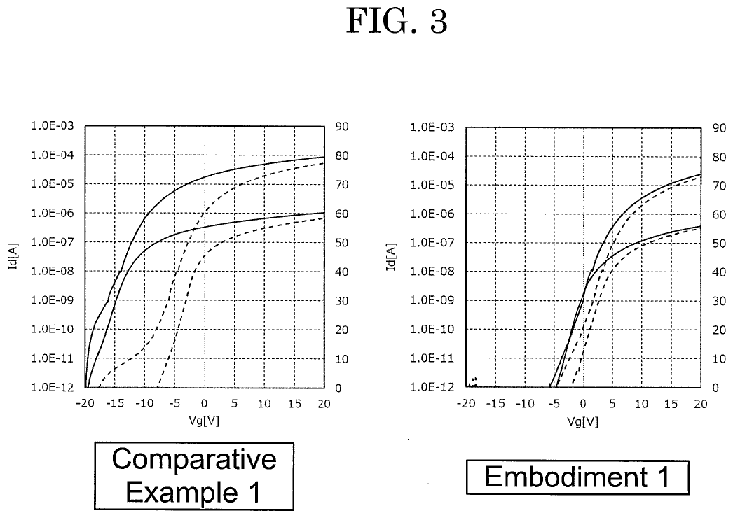

FIG. 3 is a diagram showing reliability test results for visible light of a transistor used in a radiation detecting apparatus according to an embodiment of the present invention. The reliability test shown in FIG. 3 is a reliability test for Negative Bias Temperature Illumination Stress (NBTIS). In FIG. 3, electrical characteristics of the transistor 20 before the NBTIS of each of an example 1 and a comparative example 1 are indicated by dotted lines, and electrical characteristics after the NBTIS are indicated by solid lines.

Conditions for the NBTIS reliability test are as follows.

$$\begin{matrix}Size of channel region : W / L = 3. μm / 3. μm \\ Irradiation condition : Irradiation present ( 7000 lx ) \\ Gate voltage : - 30 V \\ Source / Drain Voltage : 0 V \\ Stage temperature when stress is applied : 85 ° C \\ Stress application duration : 1000 sec\end{matrix}$$

Structures of the transistors of the example 1 and the comparative example 1 subjected to the reliability test of FIG. 3 are as follows.

$$\begin{matrix}Gate electrode 110 \backslash 120 : SiN \backslash SiO = 300 \backslash 10 nm \\ Oxide semiconductor layer 140 : 30 nm ( polycrystalline ) \\ Oxide layer 150 \backslash insulating layer 160 : SiO \backslash SiN = 300 \backslash 100 nm\end{matrix}$$

A film formation condition of the oxide layer 150 in the transistor 20 according to the example 1 are as shown in the steps (1) to (2) described above. On the other hand, in a film formation condition of an oxide layer in the transistor according to the comparative example 1, a film formation condition in a step (1′) of the comparative example 1 is different from the film formation condition in the step (1) of the example 1.

(1′) Processing conditions of an interface formation process of the comparative example 1 are as follows.

$$\begin{matrix}{SiH}_{4} / {N}_{2} O flow rate = 10 / 1000 sccm \\ Chamber pressure = 200 Pa \\ Power RF = 100 W \\ F ratio ( RF / {SiH}_{4} ) = 10. \\ Film thickness = 10 nm\end{matrix}$$

As described above, in the processing conditions of the interface film formation process of the comparative example 1, the power RF in the film formation is higher, the ratio of N₂O gas to SiH₄ gas is larger, and the ratio of the power RF to SiH₄ gas is larger than the processing conditions of the interface film formation process of the example 1. An amount of hole traps in the oxide layer formed under this condition is larger than the amount of hole traps in the oxide layer 150 of the example 1. In the following description, the processing condition (1) described above may be referred to as low-power film formation, and the processing condition (1′) may be referred to as conventional condition film formation.

As shown in FIG. 3, the threshold variation before and after the NBTIS of the transistor 20 according to the example 1 is smaller than the threshold variation before and after the NBTIS of the transistor according to the comparative example 1. This result is caused by the fact that the amount of hole traps included in the oxide layer 150 according to the example 1 is smaller than the amount of hole traps included in the oxide layer according to the comparative example 1.

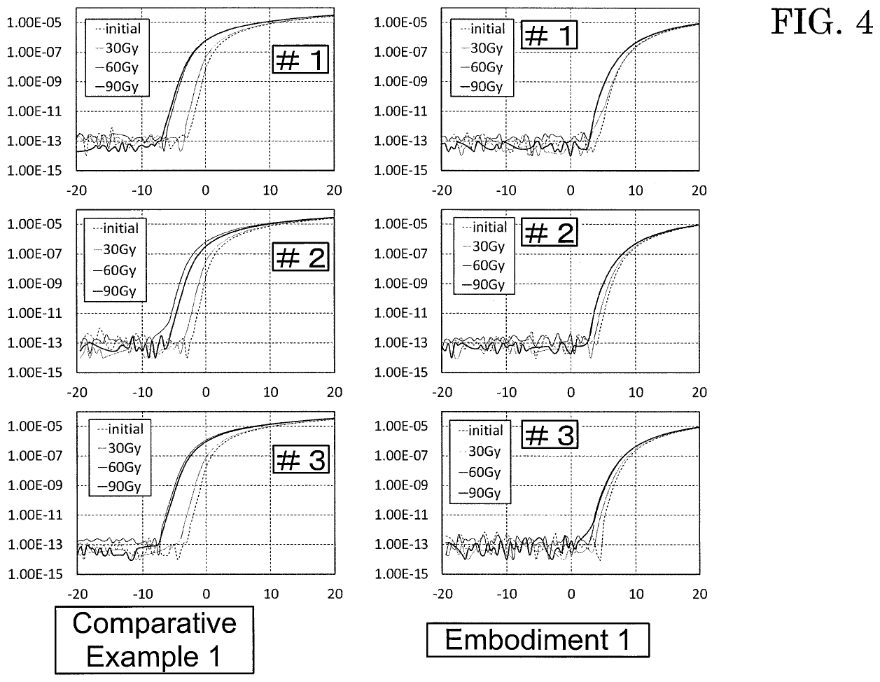

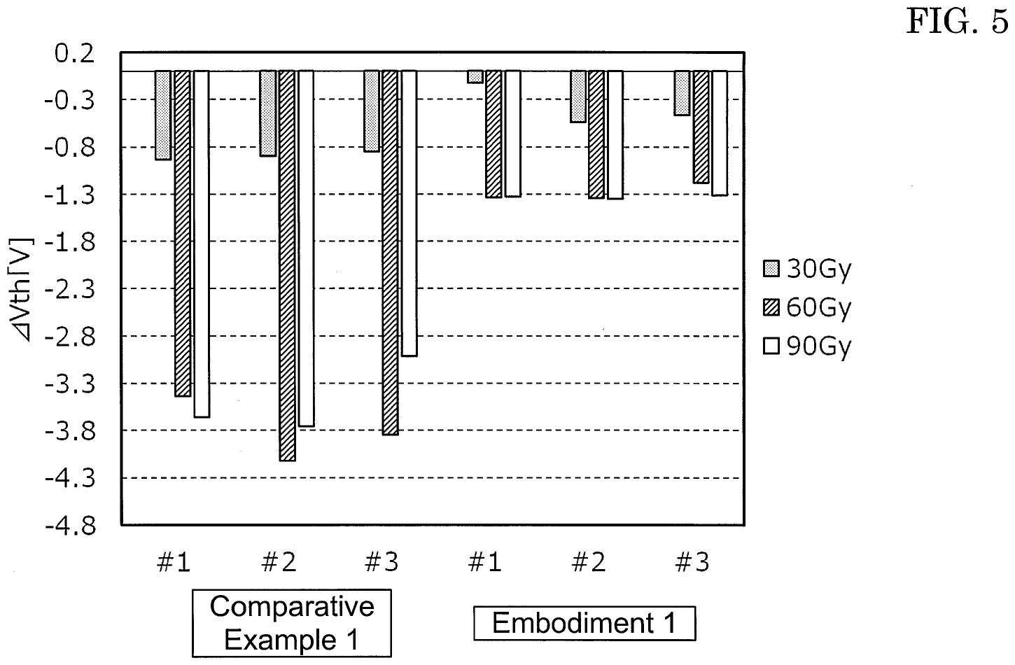

FIG. 4 and FIG. 5 are diagrams showing reliability test results of a transistor used in a radiation detector according to an embodiment of the present invention with respect to radiation. The reliability test shown in FIG. 4 is the results of an X-ray irradiation test. In FIG. 4, electrical characteristics of the transistor 20 before the X-ray irradiation are indicated by dotted lines, and electrical characteristics after the X-ray irradiation are indicated by solid lines. The results of the X-ray irradiation test of the example 1 and the comparative example 1 are shown by three (#1 to #3), respectively. The structures of the transistors of the example 1 and the comparative example 1 subjected to the X-ray irradiation test of FIG. 4 are the same as those of FIG. 3. A bar graph shown in FIG. 5 shows a variation of a threshold voltage Vth obtained from electric properties of FIG. 4 before and after the reliability test.

The conditions of the X-ray irradiation test are as follows.

$$\begin{matrix}Size of channel region : W / L = 3. μm / 3. μm \\ X - ray irradiator : MBR - 1520 R - 3 ( Hitachi Power Solutions ) \\ X - ray irradiation condition : 30 Gy , 60 Gy , 90 Gy ( 20 mA continuous irradiation ) \\ X - ray irradiation condition : Filter Al = 1 mm\end{matrix}$$

As shown in FIG. 4 and FIG. 5, the threshold variation before and after the X-ray irradiation test of the transistor 20 according to the example 1 is smaller than the threshold variation before and after the X-ray irradiation test of the transistor according to the comparative example 1. This result is the same as in FIG. 3, and is due to the fact that the amount of hole traps included in the oxide layer 150 according to the example 1 is smaller than the amount of hole traps included in the oxide layer according to the comparative example 1. As described above, similar trends are observed in the NBTIS and the X-ray radiation test. The reason why the same trends are confirmed in this way is considered to be that the threshold variation in the NBTIS and the threshold variation in the X-ray irradiation test are caused by the hole generated by the light irradiation or the X-ray irradiation being trapped in the oxide layer 150.

As described above, a correlation between the threshold variation in the NBTIS and the threshold variation in the X-ray irradiation test are confirmed, so that only the NBTIS is shown hereafter.

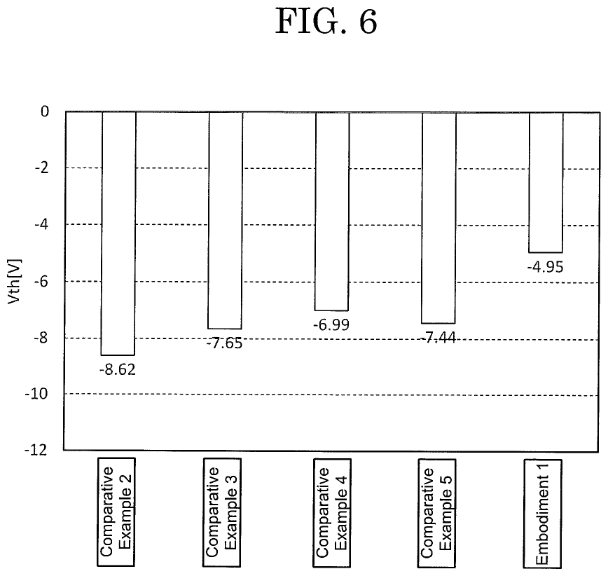

FIG. 6 is a diagram showing results of a reliability test on visible light of a transistor used in a radiation detector according to an embodiment of the present invention. The reliability test results shown in FIG. 6 are the results of evaluating the variation in the threshold voltage Vth through the NBTIS for samples having different configurations. FIG. 6 shows an example 2 and comparative examples 2 to 5 in which reliability is improved by thinning the oxide layer 150.

Common structures of the samples of the example 2 and the comparative examples 2 to 5 shown in FIG. 6 are as follows.
Oxide semiconductor layer 140: 30 nm (polycrystalline)
Film formation conditions of the oxide layer 150: steps (1′) and (2)

For the samples shown in FIG. 6, the different structures for each sample are as follows.

### [Gate Insulating Layer 110 \ 120]

Comparative Example 2: SiN\SiO=300\100 nm
Comparative Example 3: SiN\SiO=300\50 nm
Comparative Example 4: SiN\SiO=300\30 nm
Comparative Example 5: SiN\SiO=300\10 nm
Example 2: SiN\SiO=300\30 nm

### [Oxide Layer 150 \ Insulating Layer 160]

Comparative Example 2: SiO\SiN=300\100 nm
Comparative Example 3: SiO\SiN=300\100 nm
Comparative Example 4: SiO\SiN=300\100 nm
Comparative Example 5: SiOSiN=300\100 nm
Example 2: SiO\SiN=50\100 nm

As shown in FIG. 6, the variation of the threshold voltage Vth of the example 2 is smaller than that of the comparative examples 2 to 5. In other words, it can be seen that the thickness of the oxide layer 150 greatly influences the variation of the threshold voltage Vth. On the other hand, it can be seen that the thicknesses of the gate insulating layers 110 and 120 have little effect on the variation of the threshold voltage Vth. As shown in FIG. 6, in the case where the thickness of the oxide layers 150 is 50 nm or less, the reliability through the NBTIS can be improved. Similar to this, in the case where the thickness of the oxide layers 150 is 50 nm or less, the reliability through the X-ray radiation test can be improved.

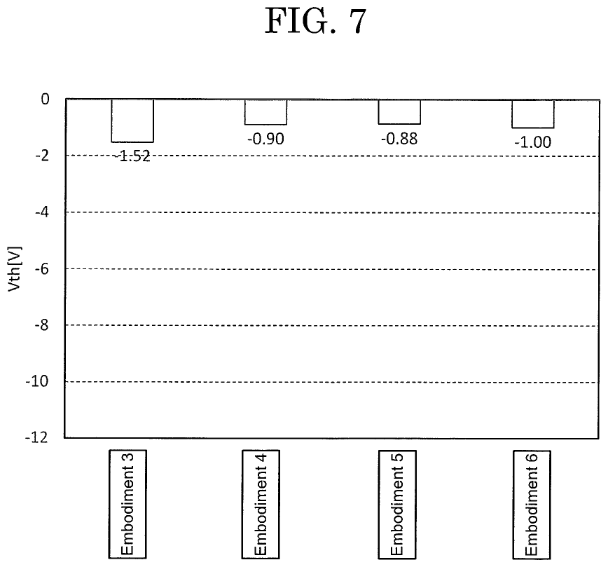

FIG. 7 is a diagram showing results of a reliability test on visible light of a transistor used in a radiation detector according to an embodiment of the present invention. The reliability test results shown in FIG. 7 are results of evaluating the variation in the threshold voltage Vth for samples having different configurations through the NBTIS. In FIG. 7, examples 3 to 6 in which reliability is improved by low-power film formation and thinning of the oxide layer 150 are shown.

For the samples of the examples 3 to 6 shown in FIG. 7, the common structure is as follows.
Oxide-semiconductor-layer 140: 30 nm (polycrystalline)
Film formation conditions of the oxide layer 150: (1) and (2). Step

For the sample shown in FIG. 7, the different structures for each sample are as follows.

### [Gate Insulating Layer 110 \ 120]

Example 3: SiN\SiO=300\50 nm
Example 4: SiN\SiO=300\50 nm
Example 5: SiN\SiO=300\30 nm
Example 6: SiN\SiO=300\10 nm

### [Oxide Layer 150 \ Insulating Layer 160]

Example 3: SiO\SiN=300\100 nm
Example 4: SiO\SiN=100\100 nm
Example 5: SiO\SiN=50\100 nm
Example 6: SiO\SiN=50\100 nm

As shown in FIG. 7, in each of the examples 3 to 6, the film formation conditions of the oxide layer 150 are low-power film formation. Therefore, the threshold voltage Vth is smaller than that in FIG. 6 in all cases. Among them, when the example 3 is compared with the examples 4 to 6, it can be seen that a thickness of the oxide layers 150 is reduced from 300 nm to 100 nm, so that the variation in the threshold voltage Vth is reduced. In other words, in the case where the film formation condition of the oxide layer 150 is low-power film formation, the thickness of the oxide layer 150 is 100 nm or less, so that the amount of hole traps contained in the oxide layer 150 can be reduced and the reliability can be improved through the NBTIS. Similar to this, in the case where the thickness of the oxide layers 150 is 100 nm or less, the reliability through the X-ray radiation test can be improved.

Each of the embodiments described above as the embodiment of the present invention can be appropriately combined as long as they are not mutually contradictory. Further, based on the transistor and the radiation detector of each embodiment, additions, deletions, or design changes of the components, or those additions, deletions, or condition changes of the steps made by a person skilled in the art as appropriate are also included in a scope of the present invention as long as it comprises the gist of the present invention.

It is to be understood that the present invention provides other operational effects that are different from operational effects provided by aspects of the embodiments described above, and those that are obvious from descriptions of the present specification or those that can be easily predicted by a person skilled in the art.

What is claimed is:

1. A radiation detector comprising:
a transistor in which an oxide semiconductor layer is used in a channel of the transistor;
a photoelectric converting layer connected to the transistor;
a wavelength converting layer facing the photoelectric converting layer and capable of emitting visible light based on radioactive rays absorbed by the wavelength converting layer; and
an oxide layer in contact with the oxide semiconductor layer between the transistor and the photoelectric converting layer, wherein a thickness of the oxide layer is 50 nm or less.

2. The radiation detector according to claim 1, wherein
the transistor includes
a gate electrode layer facing the oxide semiconductor layer and
a gate insulating layer between the oxide semiconductor layer and the gate electrode layer, and
the oxide semiconductor layer is closer to the photoelectric converting layer than the gate electrode layer.

3. The radiation detector according to claim 1, wherein the oxide layer is a silicon oxide layer.

4. The radiation detector according to claim 1, wherein the thickness of the oxide layer is 30 nm or less.

5. The radiation detector according to claim 1, wherein
the oxide layer includes a first region and a second region,
the first region is in contact with the oxide semiconductor layer, and
a thickness of the oxide layer in the first region is smaller than a thickness of the oxide layer in the second region.

6. The radiation detector according to claim 5, wherein a hole trapping property of the oxide layer in the first region is smaller than a hole trapping property of the oxide layer in the second region.

7. The radiation detector according to claim 5, wherein the oxide layer in the first region is a layer deposited under a condition of lower deposition power in a sputtering method than the oxide layer in the second region.
